(19) United States
(12) Patent Application Publication
(10) Pub. No.: US 2025/0169058 A1
(43) Pub. Date: May 22, 2025

(54) SEMICONDUCTOR DEVICE

(71) Applicant: Samsung Electronics Co., Ltd., Suwon-si (KR)

(72) Inventors: Seongjae BYEON, Suwon-si (KR); Si Nyeon KIM, Suwon-si (KR); Wonsok LEE, Suwon-si (KR); Juho LEE, Suwon-si (KR)

(73) Assignee: Samsung Electronics Co., Ltd., Suwon-si (KR)

(21) Appl. No.: 18/761,823

(22) Filed: Jul. 2, 2024

(30) Foreign Application Priority Data
Nov. 16, 2023 (KR) 10-2023-0159083

(51) Int. Cl. H10B 12/00

(52) U.S. Cl. CPC H10B 12/315; H10B 12/05; H10B 12/482

(57) ABSTRACT

A semiconductor device may include a bit line extending in a first direction on a substrate, a first insulating pattern extending in a second direction on the bit line, a channel pattern contacting a sidewall of the first insulating pattern and the bit line and including an oxide semiconductor material, a word line extending in the second direction and spaced apart from the channel pattern, a gate insulating pattern between the channel pattern and the word line, a second insulating pattern on the word line and the gate insulating pattern, and a landing pad electrically connected to the channel pattern. A second portion of the channel pattern between the gate insulating pattern and the bit line may be thicker than a first portion of the channel pattern, which may be between the gate insulating pattern and the first insulating pattern. The second direction may intersect the first direction.

### CROSS-REFERENCE TO RELATED APPLICATION

This application claims priority to and the benefit of Korean Patent Application No. 10-2023-0159083 filed in the Korean Intellectual Property Office on Nov. 16, 2023, the entire contents of which are incorporated herein by reference.

### BACKGROUND

### (a) Field

The present disclosure relates to a semiconductor device.

### (b) Description of the Related Art

Increasing the integration of semiconductor memory devices may be needed to meet the excellent performance and low prices demanded by consumers. In the case of semiconductor memory devices, increasing integration particularly may be required because the integration may be an important factor in determining the price of the product.

In the case of two-dimensional semiconductor memory devices, the integration mainly may be determined by the area occupied by a unit memory cell, and therefore may be affected greatly by the level of fine pattern formation technology. However, because ultra-expensive equipment may be required to form the fine pattern, the integration of two-dimensional semiconductor memory devices is increasing but still may be limited. Accordingly, semiconductor memory devices including vertical channel transistors, in which channels extend in the vertical direction, have been proposed.

### SUMMARY

The present disclosure relates to a semiconductor device with improved electrical characteristics by reducing contact resistance at the interface between a bit line and a channel pattern.

According to an example embodiment, a semiconductor device may include a substrate; a bit line on the substrate and extending in a first direction; a first insulating pattern on the bit line and extending in a second direction, the second direction intersecting the first direction; a channel pattern contacting a sidewall of the first insulating pattern and the bit line, the channel pattern including an oxide semiconductor material; a word line extending in the second direction and spaced apart from the channel pattern; a gate insulating pattern between the channel pattern and the word line; a second insulating pattern on the word line and the gate insulating pattern; and a landing pad electrically connected to the channel pattern. The channel pattern may include a first portion and a second portion. The first portion of the channel pattern may be between the gate insulating pattern and the first insulating pattern. The second portion of the channel pattern may be between the gate insulating pattern and the bit line. A thickness of the second portion of the channel pattern may be thicker than a thickness of the first portion of the channel pattern.

According to an example embodiment, a semiconductor device may include a substrate; a bit line on the substrate and extending in a first direction; a first insulating pattern on the bit line and extending in a second direction, the second direction intersecting the first direction; a channel pattern on a upper surface of the bit line and a sidewall of the first insulating pattern, the channel pattern including an oxide semiconductor material; a word line extending in the second direction and spaced apart from the channel pattern; a gate insulating pattern between the channel pattern and the word line; a second insulating pattern on the word line and the gate insulating pattern; and a landing pad electrically connected to the channel pattern. The channel pattern may include a first channel pattern and a second channel pattern. The first channel pattern may be between the bit line and the first insulating pattern, and the second channel pattern may be on an upper surface of the first channel pattern and a sidewall of the first insulating pattern.

According to an example embodiment, a semiconductor device may include a substrate; a bit line on the substrate and extending in a first direction; a first insulating pattern on the bit line and extending in a second direction, the second direction intersecting the first direction; a channel pattern on a upper surface of the bit line and a sidewall of the first insulating pattern, the channel pattern including an oxide semiconductor material; a word line extending in the second direction and spaced apart from the channel pattern; a gate insulating pattern between the channel pattern and the word line; a second insulating pattern on the word line and the gate insulating pattern; and a landing pad electrically connected to the channel pattern. The channel pattern may include a first channel pattern and a second channel pattern. The first channel pattern may extend from an upper surface of the bit line onto a sidewall of the first insulating pattern. The second channel pattern may be between the first channel pattern and the gate insulating pattern.

According to embodiments, it is possible to improve the electrical characteristics of the semiconductor device by reducing the contact resistance at the interface between the bit line and the channel pattern.

### BRIEF DESCRIPTION OF THE DRAWINGS

FIG. 1 is a layout diagram for describing a semiconductor device according to some embodiments.

FIG. 2A is a cross-sectional view of the semiconductor device according to an embodiment of FIG. 1 taken along lines A-A′ and B-B′.

FIG. 2B is a cross-sectional view of the semiconductor device according to an embodiment of FIG. 1 taken along lines A-A′ and B-B′.

FIG. 3 is an enlarged view of P1 in FIGS. 2A and 2B.

FIG. 4 is a cross-sectional view taken along lines A-A′ and B-B′ of FIG. 1 according to an embodiment of FIG. 1.

FIG. 5 is an enlarged view of P2 in FIG. 4.

FIGS. 6 to 23 are cross-sectional views showing a method of manufacturing a semiconductor device according to an embodiment.

FIGS. 24 to 41 are cross-sectional views showing a method of manufacturing a semiconductor device according to an embodiment.

### DETAILED DESCRIPTION

Hereinafter, the present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

Size and thickness of each constituent element in the drawings are arbitrarily illustrated for better understanding and ease of description, the following embodiments are not limited thereto. In the drawings, the thickness of layers and regions are exaggerated for clarity. In the drawings, the thickness of some layers and regions may be exaggerated for ease of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily referred to as being positioned “on” or “above” in a direction opposite to gravity. The notion that elements are “substantially the same” may indicate that the element may be completely the same and may also indicate that the elements may be determined to be the same in consideration of errors or deviations occurring during a process.

In addition, unless explicitly described to the contrary, the word “comprise”, and variations such as “comprises” or “comprising”, will be understood to imply the inclusion of stated elements but not the exclusion of any other elements.

In addition, the phrase “on a plane” means a view from a position above the object (e.g., from the top), and the phrase “on a cross-section” means a view of a cross-section of the object which is vertically cut from the side.

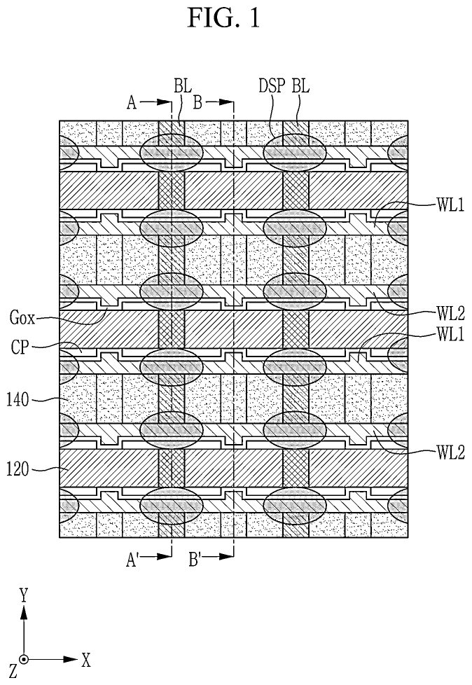

Hereinafter, a semiconductor device according to an embodiment will be described with reference to FIGS. 1 to 3 as follows.

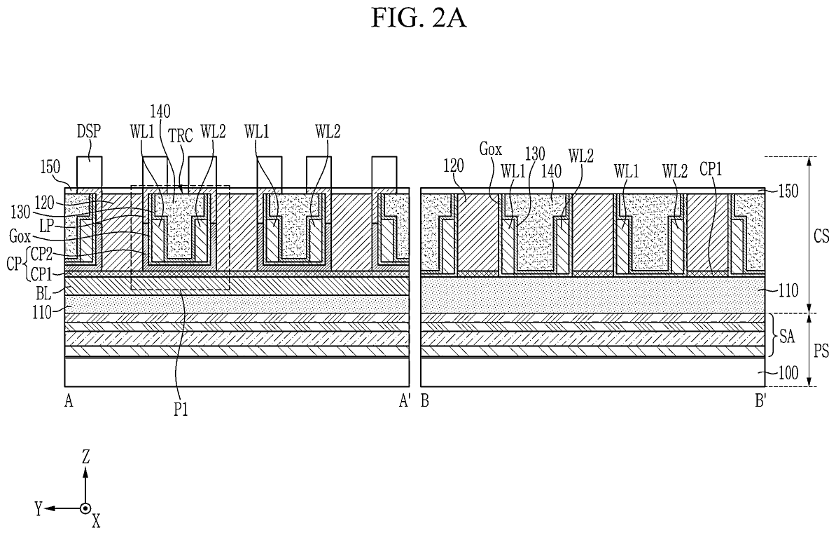

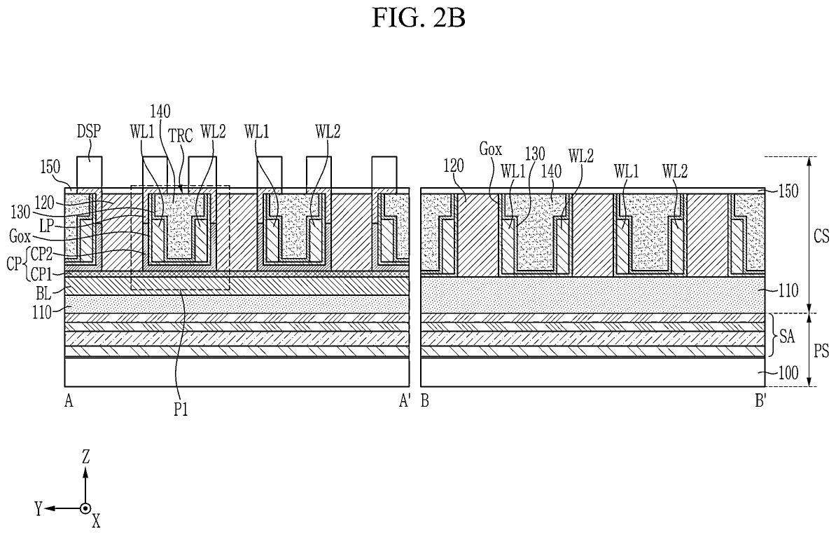

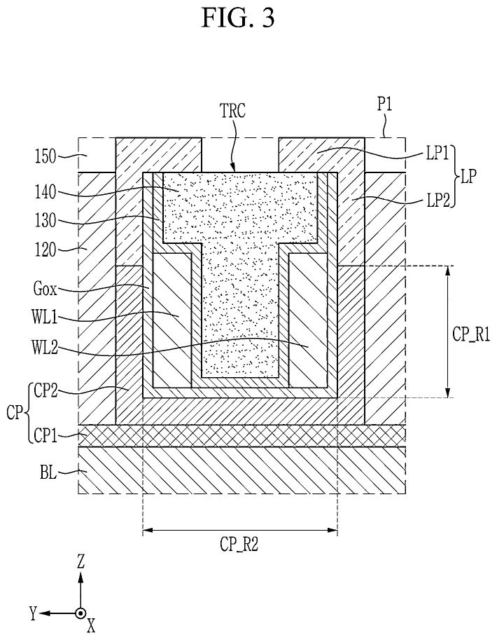

FIG. 1 is a layout diagram for describing a semiconductor device according to some embodiments. FIG. 2A is a cross-sectional view of the semiconductor device according to an embodiment of FIG. 1 taken along lines A-A′ and B-B′. FIG. 2B is a cross-sectional view of the semiconductor device according to an embodiment of FIG. 1 taken along lines A-A′ and B-B′. FIG. 3 is an enlarged view of P1 in FIGS. 2A and 2B.

Referring to FIGS. 1 to 3, a semiconductor device 100 according to an embodiment may include a peripheral circuit structure PS and a cell array structure CS located on the peripheral circuit structure PS.

The peripheral circuit structure PS may include a substrate 100, a core and peripheral circuits SA integrated on the upper surface of the substrate 100. The substrate 100 may have a structure in which a base substrate and an epitaxial layer are stacked, but is not limited thereto. For example, the substrate 100 may be a silicon substrate, a gallium arsenide substrate, a silicon germanium substrate, or a semiconductor on insulator (SOI) substrate. Hereinafter, the substrate 100 will be described as a silicon substrate.

The core and peripheral circuits SA may include NMOS and PMOS transistors integrated on the substrate 100. The core and peripheral circuits SA may be electrically connected to bit lines BL through peripheral circuit wires and peripheral circuit contact plugs. That is, sense amplifiers may be electrically connected to the bit lines BL, and each sense amplifier may amplify and output the difference in voltage levels detected by a pair of bit lines BL.

The cell array structure CS may include memory cells including a vertical channel transistor VCT. A vertical channel transistor may refer to a structure in which the channel length extends in a direction perpendicular to the upper surface of the substrate 100.

In an embodiment, the cell array structure CS may include a lower insulating layer 110, the bit line BL, a first insulating pattern 120, channel patterns CP, word lines WL1 and WL2, a gate insulating pattern Gox, a second insulating pattern 130, a third insulating pattern 140, landing pads LP, an interlayer insulating layer 150, and data storage patterns DSP.

The lower insulating layer 110 may cover the core and peripheral circuits SA, peripheral circuit wires, and peripheral circuit contact plugs on the substrate 100. The lower insulating layer 110 may include insulating layers stacked in multiple layers. For example, the lower insulating layer 110 may include a silicon oxide layer, a silicon nitride layer, a silicon oxynitride layer, and/or a low-k dielectric layer.

The bit line BL may be located on the substrate 100. For example, the lower insulating layer 110 may be located on the substrate 100, and the bit line BL may be located on the lower insulating layer 110. The bit lines BL extend along a first direction (Y direction) and may be arranged to be spaced apart in a second direction (X direction) that intersects the first direction (Y direction). For example, the second direction (X direction) may be perpendicular to the first direction (Y direction). The lower insulating layer 110 may be located to fill the space between the bit lines BL. For example, the upper surface of the lower insulating layer 110 and the upper surface of the bit line BL may be located at substantially the same level.

The bit line BL may include doped polysilicon, metal, conductive metal nitride, conductive metal silicide, conductive metal oxide, or a combination thereof. For example, the bit lines BL may include Al, Cu, Ti, Ta, Ru, W, Mo, Pt, Ni, Co, TiN, TaN, WN, NbN, TiAlN, TiSi, TiSiN, TaSi, TaSiN, RuTiN, NiSi, CoSi, IrOx, RuOx, or a combination thereof, but is not limited thereto. The bit line BL may include a single layer or multiple layers of the above-described materials.

In some embodiments, the bit line BL may include a two-dimensional semiconductor material, for example, graphene, carbon nanotubes, or a combination thereof.

According to an embodiment, the first insulating pattern 120 may be located on the bit line BL and may extend in the second direction (X direction). The first insulating pattern 120 may be arranged to intersect the bit line BL. The first insulating patterns 120 may be spaced apart along the first direction (Y direction). As the first insulating patterns 120 are spaced apart along the first direction (Y direction), channel trenches TRC may be formed. The channel trench TRC extends in the second direction (X direction) like the first insulating pattern 120, and may be arranged to be spaced apart along the first direction (Y direction).

The first insulating pattern 120 may include, for example, at least one of silicon oxide, silicon oxynitride, silicon nitride, or a low-k material with a dielectric constant smaller than that of silicon oxide, but is not limited thereto.

The low-k materials may include, for example, at least one of flowable oxide (FOX), torene silazene (TOSZ), undoped silicate glass (USG), borosilicate glass (BSG), phosphosilicate glass (PSG), borophosphosilicate glass (BPSG), plasma enhanced tetra ethyl ortho silicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, porous polymeric material or a combination thereof, but is not limited thereto.

According to an embodiment, the first insulating pattern 120 may be located spaced apart from the bit line BL. The first insulating pattern 120 may be spaced apart from the bit line BL by the channel pattern CP.

According to an embodiment, the channel pattern CP may include a first channel pattern CP1 and a second channel pattern CP2 located on the first channel pattern CP1. The channel pattern CP may be located on the bit lines BL. The channel pattern CP may include a first source/drain region and a second source/drain region. For example, the lower part of the channel pattern CP may be connected to the bit line BL to function as a first source/drain region, and the upper part of the channel pattern CP may be connected to the landing pad LP to function as the second source/drain region. And a part of the channel pattern CP between the first source/drain region and the second source/drain region may function as a channel region.

According to an embodiment, the first channel pattern CP1 may be located directly above the bit line BL. The first channel pattern CP1 may be in contact with the bit line BL.

According to the embodiment shown in FIG. 2A, the first channel pattern CP1 may include a portion extending along the first direction (Y direction). Portions of the first channel pattern CP1 extending along the first direction (Y direction) may be spaced apart along the second direction (X direction). The first channel pattern CP1 may include a portion extending along the second direction (X direction) across the bit lines BL. Portions of the first channel pattern CP1 extending along the second direction (X direction) may be spaced apart along the first direction (Y direction). The first channel pattern CP1 may have a mesh shape.

According to the embodiment shown in FIG. 2B, the first channel pattern CP1 may extend along the first direction (Y direction). The first channel patterns CP1 may be spaced apart along the second direction (X direction). Each of the first channel patterns CP2 may have a line shape. That is, in the embodiment shown in FIG. 2B, unlike the embodiment shown in FIG. 2A, the first channel patterns CP1 extend only in the Y direction along the bit line BL and do not extend in the X direction. The embodiment shown in FIG. 2B is different from the embodiment shown in FIG. 2A only in the shape and structure of the first channel pattern CP1, but other components are the same. Hereinafter, the description will be based on the embodiment shown in FIG. 2A, but the content described later may be equally applied to the embodiment shown in FIG. 2B.

According to an embodiment, the first channel pattern CP1 may be located between the bit line BL and the first insulating pattern 120. According to an embodiment, the first insulating pattern 120 may be located on the first channel pattern CP1. The first insulating patterns 120 may be located on portions of the first channel pattern CP1 extending along the second direction (X direction).

According to an embodiment, the second channel pattern CP2 may be located on the sidewall of the first insulating pattern 120 and the first channel pattern CP1. The second channel pattern CP2 may be located in the channel trench TRC. The second channel pattern CP2 may cover the bottom surface and sidewalls of the channel trench TRC. The bottom surface of the channel trench TRC may be defined as the upper surface of the first channel pattern CP1. The sidewall of the channel trench TRC may be defined as the sidewall of the first insulating pattern 120. The second channel pattern CP2 may cover the upper surface of the first channel pattern CP1 and the sidewall of the first insulating pattern 120. Accordingly, the second channel pattern CP2 may have a “U” shape on a cross-section cut along the Y and Z directions.

According to an embodiment, the second channel pattern CP2 may be located right by the sidewall of the first insulating pattern 120. The second channel pattern CP2 may extend along the sidewall of the first insulating pattern 120. The second channel pattern CP2 may contact the sidewall of the first insulating pattern 120. In some embodiments, although not illustrated, the second channel pattern CP2 may be above the first insulating pattern 120.

According to an embodiment, the second channel pattern CP2 may have a conformal shape. The second channel pattern CP2 may cover the upper surface of the first channel pattern CP1 and the sidewall of the first insulating pattern 120 with a certain thickness.

The upper surface of the second channel pattern CP2 adjacent to the sidewall of the first insulating pattern 120 may be located at a lower level than the upper surface of the first insulating pattern 120. The upper surface of the second channel pattern CP2 adjacent to the sidewall of the first insulating pattern 120 may contact the landing pad LP, which will be described later.

The second channel patterns CP2 may be arranged to be spaced apart along the first direction (Y direction) in the channel trench TRC. The second insulating pattern 130 and the third insulating pattern 140, which will be described later, may be located between the second channel patterns CP2 adjacent in the first direction (Y direction).

According to an embodiment, the first channel pattern CP1 and the second channel pattern CP2 may include an oxide semiconductor material. The oxide semiconductor material may be a combination of at least two of In, Ga, Zn, Al, Sn, and Hf, but is not limited thereto. The oxide semiconductor material may further include a material such as Si, Mg, Ta, La, Nd, Ce, Sc, Cr, Co, Nb, Mo, Ba, Gd, Ti, W, Pd, Ru, Ni, or Mn added to the above composition.

For example, the first channel pattern CP1 and the second channel pattern CP2 may include indium gallium zinc oxide (IGZO), indium tin zinc oxide (ITZO), indium zinc oxide (IZO), zinc oxide (ZnO), zinc tin oxide (ZTO), zinc oxynitride (ZnON), zirconium zinc tin oxide (ZZTO), tin oxide (SnO), hafnium indium zinc oxide (HIZO), gallium zinc tin oxide (GZTO), aluminum zinc tin oxide (AZTO), ytterbium gallium zinc oxide (YGZO), indium gallium oxide (IGO), or a combination thereof. However, it is not limited to this, and the oxide semiconductor material included in the first channel pattern CP1 and the second channel pattern CP2 may be changed in various ways.

According to an embodiment, the first channel pattern CP1 and the second channel pattern CP2 may include different oxide semiconductor materials. For example, the second channel pattern CP2 may include IGZO, and the first channel pattern CP1 may exclude at least one of indium oxide, zinc oxide, and gallium oxide or may further include other oxides. Alternatively, the oxide semiconductor material of the first channel pattern CP1 and the oxide semiconductor material of the second channel pattern CP2 may have the same composition but different composition ratios. For example, when the first channel pattern CP1 and the second channel pattern CP2 include IGZO, the composition ratio of indium, gallium, zinc, and oxygen of the first channel pattern CP1 and the composition ratio of indium, gallium, zinc, and oxygen of the second channel pattern CP2 may be different.

According to an embodiment, the first channel pattern CP1 may include an oxide semiconductor material with a higher indium composition ratio than that of the material of the second channel pattern CP2. As the composition ratio of indium increases, contact resistance may be improved (reduced). According to an embodiment, the second channel pattern CP2 may include an oxide semiconductor material with a higher gallium composition ratio than that of the material of the first channel pattern CP1. The higher the composition ratio of gallium, the better the reliability. Here, improving reliability may mean reducing changes in film quality that occur as the semiconductor device operates.

According to an embodiment, the first channel pattern CP1 may be formed by patterning an oxide semiconductor material layer deposited through a physical vapor deposition (PVD) process. According to an embodiment, the second channel pattern CP2 may be formed by patterning an oxide semiconductor material layer deposited through an atomic layer deposition (ALD) process.

In the ALD process, O₃ is injected as a reactant along with a precursor. Accordingly, when an oxide semiconductor material layer is deposited on a metal layer using an ALD process, metal oxide is generated at the interface between the metal layer and the oxide semiconductor material layer, which may adversely affect the contact characteristics between the metal layer and the oxide semiconductor material layer. For example, the contact resistance between the metal layer and the oxide semiconductor material layer may increase, or the metal layer and the oxide semiconductor material layer may not be properly connected.

Since the above-described embodiment uses a PVD process when depositing an oxide semiconductor material layer to form the first channel pattern CP1 on the bit line BL corresponding to the metal layer, the contact characteristics between the bit line BL and the first channel pattern CP1 may be improved by reducing oxidation of the interface of the bit line BL and the first channel pattern CP1.

Meanwhile, the ALD process has superior step coverage compared to the PVD process, so the ALD process may be used to deposit an oxide semiconductor material layer to form the second channel pattern CP2 that covers the sidewalls and bottom surface of the channel trench TRC.

According to the above description, the channel pattern CP may cover the sidewall of the first insulating pattern 120 and the upper surface of the bit line BL. Specifically, the first channel pattern CP1 may cover the top surface of the bit line BL, and the second channel pattern CP2 may cover the sidewall of the first insulating pattern 120 and the upper surface of the bit line BL located between the first insulating patterns 120 adjacent along the first direction (Y direction).

Referring to FIG. 3, the channel pattern CP may include a first portion CP_R1 located between the gate insulating pattern Gox and the first insulating pattern 120, and a second portion CP_R2 located between the gate insulating pattern Gox and the bit line BL. The first portion CP_R1 may include a portion of the second channel pattern CP2, and the second portion CP_R2 may include a portion of the first channel pattern CP1 and a portion of the second channel pattern CP2. The thickness of the second portion CP_R2 may be thicker than the thickness of the first portion CP_R1.

The word lines WL1 and WL2 may extend in the second direction (X direction) across the bit lines BL and may be disposed to be spaced apart along the first direction (Y direction). The word lines WL1 and WL2 may be spaced apart from the bit line BL in a third direction (Z direction).

A pair of word lines WL1 and WL2 may be located between the second channel patterns CP2 in the channel trench TRC. A pair of word lines WL1 and WL2 may be located between the second channel pattern CP2 covering both sidewalls of the channel trench TRC. Each of the word lines WL1 and WL2 includes one surface and the other surface, which is an opposite surface of the one surface, and a pair of word lines WL1 and WL2 located in the channel trench TRC may be disposed so that each of their one surfaces faces each other.

According to an embodiment, the word lines WL1 and WL2 may be spaced apart from the channel pattern CP. The word lines WL1 and WL2 may be spaced apart from the channel pattern CP by the gate insulating pattern Gox, which will be described later.

The word lines WL1 and WL2 may include upper and lower surfaces facing each other in the third direction (Z direction). The lower surfaces of the word lines WL1 and WL2 may face the bit line BL with the gate insulating pattern Gox and the channel pattern CP interposed therebetween. The upper surfaces of the word lines WL1 and WL2 may face the landing pad LP with the second insulating pattern 130 and the third insulating pattern 140, which will be described later, interposed therebetween.

The upper surfaces of the word lines WL1 and WL2 are shown as located at a higher level than the upper surface of the second channel pattern CP2 adjacent to the sidewall of the first insulating pattern 120, but example embodiments are not limited thereto, and the upper surfaces of the word lines WL1 and WL2 may be located substantially the same or a lower level.

The word lines WL1 and WL2 may include, for example, doped polysilicon, metal, conductive metal nitride, conductive metal silicide, conductive metal oxide, or a combination thereof. The word lines WL1 and WL2 may be made of, for example, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but is not limited thereto.

The word lines WL1 and WL2 may include a single layer or multiple layers of the materials described above. In some embodiments, the word lines WL1 and WL2 may include a two-dimensional semiconductor material, for example, graphene, carbon nanotubes, or a combination thereof.

The gate insulation pattern Gox may be located between the channel pattern CP and the word lines WL1 and WL2. The gate insulating pattern Gox may be located on the second channel pattern CP2 in the channel trench TRC. The gate insulation pattern Gox may conformally cover both sidewalls of the second channel pattern CP2 facing each other in the channel trench TRC, and the upper surface of the second channel pattern CP2 located between the facing both sidewalls of the second channel pattern CP2.

The gate insulating pattern Gox covering the sidewall of the second channel pattern CP2 may extend further in the third direction (Z direction). The gate insulating pattern Gox is shown extending to substantially the same level as the upper surface of the first insulating pattern 120, but is not limited thereto. For example, the top surface of the gate insulating pattern Gox may be located at a lower level than the upper surface of the first insulating pattern 120. The top surface of the gate insulation pattern Gox may be located at a level substantially equal to or higher than the upper surface of the word lines WL1 and WL2.

According to an embodiment, the gate insulating pattern Gox may overlap the first channel pattern CP1 and the second channel pattern CP2 in the third direction (Z direction), and may overlap the second channel pattern CP2 in the first direction (Y direction). A portion of the gate insulating pattern Gox that does not overlap the second channel pattern CP2 may contact the landing pad LP, which will be described later.

The gate insulating pattern Gox may include one surface in contact with the second channel pattern CP2 and the other surface, which is opposite to the one surface. The other surface of the gate insulating pattern Gox may be in contact with the word lines WL1 and WL2 and the second insulating pattern 130, which will be described later. The other surface of the gate insulating pattern Gox may be in contact with the lower surface of the word lines WL1 and WL2 and the surface facing the second channel pattern CP2. A portion of the other surface of the gate insulating pattern Gox that is not in contact with the word lines WL1 and WL2 may be in contact with the second insulating pattern 130.

The gate insulating pattern Gox may include silicon oxide, silicon oxynitride, a high dielectric constant material having a higher dielectric constant than silicon oxide, or a combination thereof. The high dielectric constant material may include metal oxide or metal nitride. The high dielectric constant material may include, for example, HfO₂, HfSiO, HfSiON, HfTaO, HfTiO, HfZrO, ZrO₂, Al₂O₃, or a combination thereof. However, it is not limited thereto, and the material included in the gate insulating pattern Gox may be changed in various ways.

The second insulating pattern 130 and the third insulating pattern 140 may be located in the channel trench TRC. The second insulating pattern 130 and the third insulating pattern 140 may be located on the word lines WL1 and WL2 and the gate insulating pattern Gox.

The second insulating pattern 130 may contact the word lines WL1 and WL2 and the gate insulating pattern Gox. The second insulating pattern 130 may conformally cover the word lines WL1 and WL2 and the gate insulating pattern Gox. The second insulating pattern 130 may cover the upper surface and sidewalls facing each other of the word lines WL1 and WL2 located in the channel trench TRC. The second insulating pattern 130 may cover a portion of the gate insulating pattern Gox that is not covered by the word lines WL1 and WL2 in the channel trench TRC. The second insulating pattern 130 may cover the upper surface of the gate insulating pattern Gox located between the word lines WL1 and WL2. The second insulating pattern 130 may cover a sidewall of the gate insulating pattern Gox protruding in the third direction (Z direction) more than the upper surfaces of the word lines WL1 and WL2.

The third insulating pattern 140 may be located on the second insulating pattern 130. The third insulating pattern 140 may be spaced apart from the word lines WL1 and WL2 and the gate insulating pattern Gox by the second insulating pattern 130. That is, the second insulating pattern 130 may be located between the word lines WL1 and WL2 and the third insulating pattern 140, and between the gate insulating pattern Gox and the third insulating pattern 140. The third insulating pattern 140 may fill the remaining channel trench TRC after the second channel pattern CP2, the gate insulating pattern Gox, the word lines WL1 and WL2, and the second insulating pattern 130 are formed.

The third insulating pattern 140 may include a vertical portion located between the word lines WL1 and WL2 and a horizontal portion located above the upper surfaces of the word lines WL1 and WL2. Accordingly, the third insulating pattern 140 may have a “T” shape on a cross-section cut along the Y and Z directions. The vertical portion of the third insulating pattern 140 may extend in the third direction (Z direction) from the horizontal portion of the third insulating pattern 140 toward the bit line BL. The vertical portion of the third insulating pattern 140 may be closer to the bit line BL than the horizontal portion of the third insulating pattern 140. On a cross-section along the Y and Z directions, the horizontal portion of the third insulating pattern 140 may have a width (Y-direction width) greater than the vertical portion of the third insulating pattern 140.

The second insulating pattern 130 and the third insulating pattern 140 may include, for example, at least one of silicon oxide, silicon oxynitride, silicon nitride, or a low-k material with a dielectric constant smaller than silicon oxide, but is not limited thereto. The second insulating pattern 130 and the third insulating pattern 140 may include different materials. For example, the second insulating pattern 130 may include silicon nitride, and the third insulating pattern 140 may include silicon oxide.

If the second insulating pattern 130 and the third insulating pattern 140 include different materials, they may be formed sequentially, but if the second insulating pattern 130 and the third insulating pattern 140 include the same material, they may be integrally formed.

The landing pad LP may be disposed to overlap at least a portion of the channel pattern CP in the third direction (Z direction). The landing pads LP may be disposed to be spaced apart from each other in the first direction (Y direction) and the second direction (X direction). The landing pads LP may be arranged in a matrix form, but this is only an example and is not limited thereto. The landing pads LP may be arranged in various shapes, such as a honeycomb shape.

Additionally, the landing pad LP may have a circular, oval, rectangular, square, rhombus, or hexagonal shape on a plane, but the planar shape of the landing pad LP is not limited thereto.

The landing pad LP may be electrically connected to the channel pattern CP. The landing pad LP may contact at least a portion of the channel pattern CP. In some embodiments, the landing pads LP may be located between the first insulating pattern 120 and the gate insulating pattern Gox.

The landing pad LP may include a first portion LP1 extending in the first direction (Y direction) and a second portion LP2 extending from the first portion LP1 in the third direction (Z direction). The first portion LP1 of the landing pad LP may be located on the upper surface of the gate insulating pattern Gox, the upper surface of the second insulating pattern 130, and the upper surface of the third insulating pattern 140. The lower surface of the first part LP1 of the landing pad LP is shown to be located at substantially the same level as the upper surface of the first insulating pattern 120 and the upper surface of the third insulating pattern 140, but is limited thereto. For example, the lower surface of the first portion LP1 of the landing pad LP may be located at a lower level than the upper surfaces of the first and third insulating patterns 120 and 140.

The second portion LP2 of the landing pad LP extends in the third direction (Z direction) from the first part LP1 toward the bit line BL, and may contact the upper surface of the second channel pattern CP2. Accordingly, the landing pad LP may be electrically connected to the second channel pattern CP2 and may be electrically connected to the first channel pattern CP1 through the second channel pattern CP2.

One side of the second portion LP2 of the landing pad LP may be in contact with the first insulating pattern 120, and the other side, which is opposite to one side of the second portion LP2 of the landing pad LP, may be in contact with the gate insulating pattern Gox. The lower surface of the second portion LP2 of the landing pad LP may be located at a lower level than the upper surface of the word lines WL1 and WL2, but is not limited thereto. For example, the lower surface of the second portion LP2 of the landing pad LP may be located at a level substantially equal to or higher than the upper surface of the word lines WL1 and WL2.

The landing pad LP may include doped polysilicon, metal, conductive metal nitride, conductive metal oxide, or a combination thereof. For example, the landing pad LP may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but is not limited thereto.

The interlayer insulating layer 150 may fill the space between landing pads LP disposed to be spaced apart in the first direction (Y direction) on the first and third insulating patterns 120 and 140. For example, the lower surface of the interlayer insulating layer 150 may be located at substantially the same level as the lower surface of the first portion LP1 of the landing pads LP, but is not limited thereto.

Data storage patterns DSP may be respectively disposed on the landing pad LP. The data storage patterns DSP may each be electrically connected to the channel pattern CP through the landing pad LP. As shown in FIG. 1, the data storage patterns DSP may be arranged in a matrix form along the first direction (Y direction) and the second direction (X direction).

In an embodiment, the data storage pattern DSP may be a capacitor, and may include lower and upper electrodes and a capacitor dielectric layer interposed therebetween. When the data storage pattern DSP is a capacitor, the lower electrode may be in contact with the landing pad LP, and the lower electrode may have various shapes such as circular, oval, rectangular, square, rhombus, and hexagon on a plane.

In contrast, the data storage pattern DSP may be a variable resistance pattern capable of being switched between two resistance states by electrical pulses applied to the memory element. For example, the data storage pattern DSP may include a phase-change material in which crystal state changes depending on the amount of current, a perovskite compound, a transition metal oxide, magnetic material, ferromagnetic materials, or antiferromagnetic materials.

The channel pattern CP of the semiconductor device according to an embodiment includes the first channel pattern CP1 formed by patterning an oxide semiconductor material layer deposited on the bit line BL using a PVD process, and the second channel pattern CP2 formed by patterning an oxide semiconductor material layer deposited in the channel trench TRC using an ALD process. Accordingly, the thickness of the second portion CP_R2 of the channel pattern CP located between the gate insulating pattern Gox and the bit line BL may be thicker than the thickness of the first portion CP_R1 of the channel pattern CP located between the gate insulating pattern Gox and the first insulating pattern 120. Additionally, the first channel pattern CP1 may be located between the bit line BL and the first insulating pattern 120. As the first channel pattern CP1 located directly above the bit line BL is formed using a PVD process, it is possible to reduce oxidation of the interface between the bit line BL and the first channel pattern CP1, and improve the contact between the bit line BL and the first channel pattern CP.

Hereinafter, another embodiment of a semiconductor device will be described with reference to FIGS. 1, 4, and 5. In the following embodiments, the same components as the above-described embodiments will be referred to by the same reference numerals, and redundant descriptions will be omitted or simplified, focusing on explaining the differences.

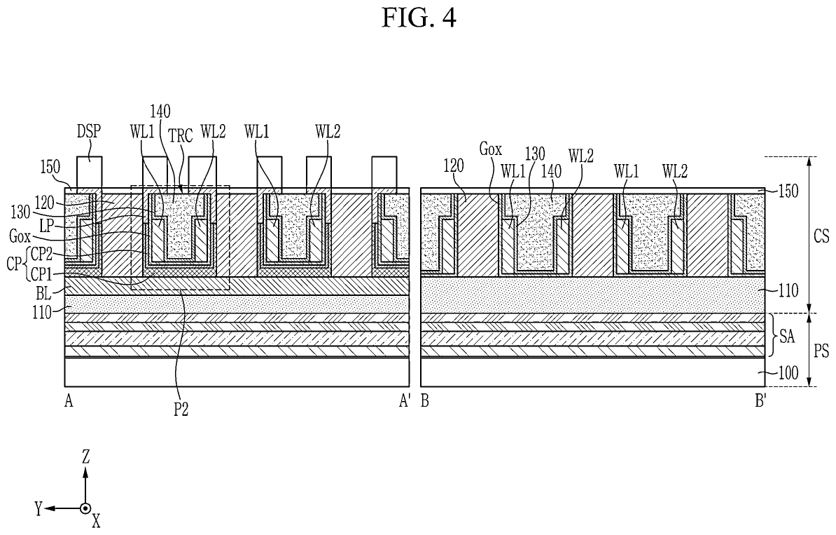

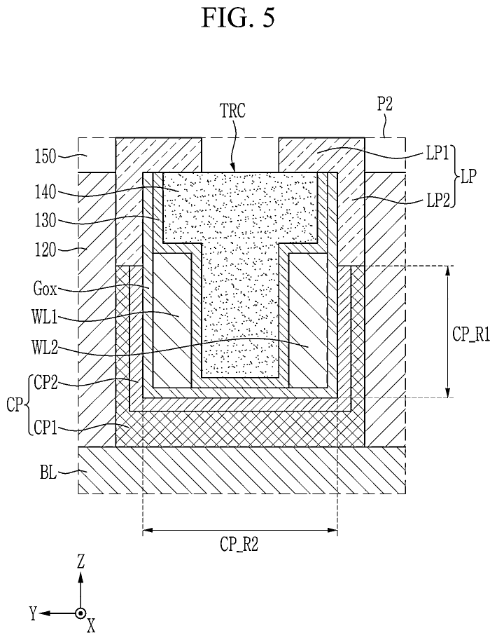

FIG. 4 is a cross-sectional view taken along lines A-A′ and B-B′ of FIG. 1 according to an embodiment of FIG. 1. FIG. 5 is an enlarged view of P2 in FIG. 4.

Referring to FIGS. 4 and 5, like the embodiment shown in FIGS. 2A, 2B, and 3, the first insulating pattern 120 may be located on the bit line BL, and the channel pattern CP may be located on the sidewall of the first insulating pattern 120 and the bit line BL. As the first insulating patterns 120 are spaced apart along the first direction (Y direction), channel trenches TRC may be formed.

However, according to the embodiment shown in FIGS. 4 and 5, unlike the embodiment shown in FIGS. 2A, 2B, and 3, the first insulating pattern 120 may be located directly above the bit line BL, and the first channel pattern CP1 may not be located between the bit line BL and the first insulating pattern 120.

According to the embodiment shown in FIGS. 4 and 5, the bottom surface of the channel trench TRC may be defined as the upper surface of the bit line BL, and the side surface of the channel trench TRC may be defined as the sidewall of the first insulating pattern 120. The channel pattern CP may be located in the channel trench TRC. The channel pattern CP may be located on the upper surface of the bit line BL and the sidewall of the first insulating pattern 120. The channel pattern CP may contact the sidewall of the first insulating pattern 120 and the upper surface of the bit line BL.

According to the embodiment shown in FIGS. 4 and 5, unlike the embodiment shown in FIGS. 2A, 2B, and 3, the channel pattern CP may include the first channel pattern CP1 located directly above the upper surface of the bit line BL and on the sidewall of the first insulating pattern 120, and the second channel pattern CP2 located on the first channel pattern CP1. The first channel pattern CP1 may contact the upper surface of the bit line BL and the sidewall of the first insulating pattern 120. The second channel pattern CP2 may be spaced apart from the upper surface of the bit line BL and the sidewall of the first insulating pattern 120 by the first channel pattern CP1. The first channel pattern CP1 may be located between the bit line BL and the second channel pattern CP2 and between the first insulating pattern 120 and the second channel pattern CP2.

The first channel pattern CP1 may cover the upper surface of the bit line BL and the sidewall of the first insulating pattern 120. The first channel pattern CP1 may extend from the upper surface of the bit line BL onto the sidewall of the first insulating pattern 120. The first channel pattern CP1 may include a horizontal portion extending in the first direction (Y direction) along the bit line BL, and a vertical portion extending from the horizontal portion in the third direction (Z direction) along the sidewall of the first insulating pattern 120.

The second channel pattern CP2 may cover the upper surface of the bit line BL and the sidewall of the first insulating pattern 120 on the first channel pattern CP1. The second channel pattern CP2 may include a horizontal portion extending in the first direction (Y direction) along the bit line BL, and a vertical portion extending from the horizontal portion in the third direction (Z direction) along the sidewall of the first insulating pattern 120. The horizontal portion of the second channel pattern CP2 may be positioned on the horizontal portion of the first channel pattern CP1. The vertical portion of the second channel pattern CP2 may be positioned on the vertical portion of the first channel pattern CP1.

As described above with reference to FIGS. 2A, 2B, and 3, the first channel pattern CP1 and the second channel pattern CP2 may include an oxide semiconductor material. The oxide semiconductor material may be a combination of at least two of In, Ga, Zn, Al, Sn, and Hf, but is not limited thereto. The oxide semiconductor material may include a material such as Si, Mg, Ta, La, Nd, Ce, Sc, Cr, Co, Nb, Mo, Ba, Gd, Ti, W, Pd, Ru, Ni, or Mn added to the above composition.

The first channel pattern CP1 and the second channel pattern CP2 may include indium gallium zinc oxide (IGZO), indium tin zinc oxide (ITZO), indium zinc oxide (IZO), zinc oxide (ZnO), zinc tin oxide (ZTO), zinc oxynitride (ZnON), zirconium zinc tin oxide (ZZTO), tin oxide (SnO), hafnium indium zinc oxide (HIZO), gallium zinc tin oxide (GZTO), aluminum zinc tin oxide (AZTO), ytterbium gallium zinc oxide (YGZO), indium gallium oxide (IGO), or a combination thereof. However, it is not limited to this, and the oxide semiconductor material included in the first channel pattern CP1 and the second channel pattern CP2 may be changed in various ways.

In some embodiments, the first channel pattern CP1 may include an oxide semiconductor material with a higher indium composition ratio than that of the second channel pattern CP2. As the composition ratio of indium increases, contact resistance may be improved (reduced).

In some embodiments, the second channel pattern CP2 may include an oxide semiconductor material with a higher gallium composition ratio than that of the first channel pattern CP1. The higher the composition ratio of gallium, the better the reliability.

In some embodiments, the first channel pattern CP1 and the second channel pattern CP2 may include IGZO, but are not limited thereto, and the oxide semiconductor material included in the first channel pattern CP1 and the second channel pattern CP2 may be varied.

The composition ratio of indium, gallium, zinc, and oxygen of the first channel pattern CP1 and the composition ratio of indium, gallium, zinc, and oxygen of the second channel pattern CP2 may be different. In some embodiments, the IGZO of the first channel pattern CP1 may have a higher indium composition ratio than the IGZO of the second channel pattern CP2, and the IGZO of the second channel pattern CP2 may have a higher gallium composition ratio than the IGZO of the first channel pattern CP1.

As described above with reference to FIGS. 2A, 2B, and 3, the first channel pattern CP1 may be formed by patterning an oxide semiconductor material layer deposited through a physical vapor deposition (PVD) process. The second channel pattern CP2 may be formed by patterning an oxide semiconductor material layer deposited through an atomic layer deposition (ALD) process.

In the ALD process, as O₃ is injected, when an oxide semiconductor material layer is deposited on the bit line BL containing a metal using the ALD process, a metal oxide may be generated at the interface between the bit line BL and the oxide semiconductor material layer.

Since O₃ is not injected in the PVD process, when depositing the oxide semiconductor material layer on the bit line BL using the ALD process, less metal oxide may be generated on the interface between the bit line BL and the oxide semiconductor material layer compared to when depositing using the ALD process.

In other words, when depositing an oxide semiconductor material layer of the first channel pattern CP1 directly above the bit line BL using a PVD process, it is possible to reduce the metal oxide generated on the interface of the bit line BL and the first channel pattern CP1, and reduce the contact resistance of the bit line BL.

However, in the case of the PVD process, the material to be deposited is vaporized in a vacuum chamber and then the vaporized particles are deposited on the substrate, which can be performed in a high vacuum state without impurities. In such a high vacuum state, linearity may be improved, but step coverage may not be excellent because deposition does not occur properly on the sidewalls of the pattern with steps. For example, the PVD process may have poor step coverage of the deposited material compared to the CVD process or ALD process. Accordingly, in the embodiments shown in FIGS. 4 and 5, unlike the embodiments shown in FIGS. 2A, 2B, and 3, the thickness of the portion of the first channel pattern CP1 located between the bit line BL and the second channel pattern CP2 may be thicker than the thickness of the portion of the first channel pattern CP1 located between the first insulating pattern 120 and the second channel pattern CP2.

The oxide semiconductor material layer corresponding to the second channel pattern CP2 that does not contact the bit line BL may be deposited using an ALD process. Accordingly, the second channel pattern CP2 may have a conformal shape, and the thickness of the portion of the second channel pattern CP2 extending along the sidewall of the first insulating pattern 120 and the thickness of the portion of the second channel pattern CP2 extending along the bit line BL may be substantially the same.

According to the embodiment illustrated in FIGS. 4 and 5, the thickness of the second portion CP_R2 of the channel pattern CP located between the gate insulating pattern Gox and the bit line BL may be thicker than the thickness of the first portion CP_R1 of the channel pattern CP located between the gate insulating pattern Gox and the first insulating pattern 120. Unlike the embodiment shown in FIGS. 2A, 2B, and 3, the first portion CP_R1 and the second portion CP_R2 may both include the portion of the first channel pattern CP1 and the portion of the second channel pattern CP2. The thickness of the portion of the second channel pattern CP2 located between the gate insulating pattern Gox and the bit line BL may be substantially the same as the thickness of the portion of the second channel pattern CP2 located between the gate insulating pattern Gox and the first insulating pattern 120. The thickness of the portion of the first channel pattern CP1 located between the gate insulating pattern Gox and the bit line BL may be thicker than the thickness of the portion of the first channel pattern CP1 located between the gate insulating pattern Gox and the first insulating pattern 120. Accordingly, the thickness of the second portion CP_R2 of the channel pattern CP located between the gate insulating pattern Gox and the bit line BL may be thicker than the thickness of the first portion CP_R1 of the channel pattern CP located between the gate insulating pattern Gox and the first insulation pattern 120.

As in the embodiment shown in FIGS. 2A, 2B, and 3, the word lines WL1 and WL2 may be located on the channel pattern CP, but may be separated from the channel pattern CP by the gate insulating pattern Gox.

In the embodiment shown in FIGS. 2A, 2B, and 3, the word lines WL1 and WL2 may overlap the second channel pattern CP2 in the first direction (Y direction) and the third direction (Z direction), and may overlap the first channel pattern CP1 only in the third direction (Z direction). According to the embodiment shown in FIGS. 4 and 5, the word lines WL1 and WL2 may overlap the first channel pattern CP1 and the second channel pattern CP2 in the first direction (Y direction) and the third direction (Z direction).

The gate insulating pattern Gox may be located between the second channel pattern CP2 and the word lines WL1 and WL2. In the embodiment shown in FIGS. 2A, 2B, and 3, only the second channel pattern CP2 is located between the gate insulating pattern Gox and the sidewall of the first insulating pattern 120. According to the embodiment shown in FIGS. 4 and 5, unlike the embodiment shown in FIGS. 2A, 2B, and 3, the first channel pattern CP1 and the second channel pattern CP2 may be located between the gate insulating pattern Gox and the sidewalls of the first insulating pattern 120.

In FIGS. 4 and 5, it is shown that the upper surfaces of the first channel pattern CP1 and the second channel pattern CP2 are located substantially at the same level between the gate insulating pattern Gox and the sidewall of the first insulating pattern 120, but it is not limited thereto. For example, the upper surface of the second channel pattern CP2 may be located at a higher level than the upper surface of the first channel pattern CP1.

Meanwhile, the landing pad LP may be located on the channel pattern CP located between the gate insulating pattern Gox and the sidewall of the first insulating pattern 120. As in the embodiment shown in FIGS. 2A, 2B, and 3, the landing pad LP may include the first portion LP1 extending in the first direction (Y direction) and the second portion LP2 extending in the third direction (Z direction) from the first portion LP1 toward the bit line BL.

According to the embodiment shown in FIGS. 4 and 5, unlike the embodiment shown in FIGS. 2A, 2B, and 3, the landing pad LP may contact the first channel pattern CP1 and the second channel pattern CP2. The second portion LP2 of the landing pad LP may contact the upper surface of the first channel pattern CP1 and the upper surface of the second channel pattern CP2. Accordingly, the landing pad LP may be electrically connected to the first channel pattern CP1 and the second channel pattern CP2.

The channel pattern CP of the semiconductor device according to the embodiment shown in FIGS. 4 and 5 includes the first channel pattern CP1 and the second channel pattern CP2 corresponding to an oxide semiconductor material layer deposited using a PVD process and an oxide semiconductor material layer deposited using an ALD process, respectively, in the channel trench TRC. Accordingly, a thickness of the second portion CP_R2 of the channel pattern CP located between the gate insulating pattern Gox and the bit line BL may be thicker than a thickness of the first portion CP_R1 of the channel pattern CP located between the gate insulating pattern Gox and the first insulating pattern 120. As the first channel pattern CP1 located directly above the bit line BL is formed using a PVD process, it is possible to reduce oxidation of the interface between the bit line BL and the first channel pattern CP1, and improve the contact between the bit line BL and the first channel pattern CP.

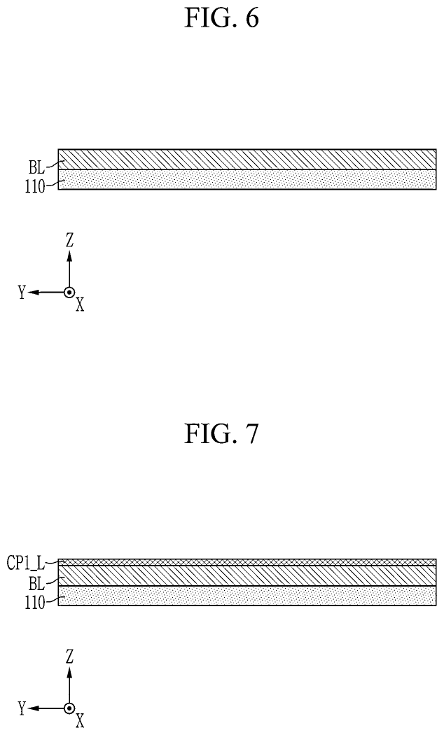

Hereinafter, with reference to FIGS. 6 to 23, a method of manufacturing a semiconductor device according to the embodiment shown in FIGS. 2A and 3 will be described. In FIGS. 6 to 23, for convenience, the peripheral circuit structure PS of FIGS. 2A and 3 is omitted, and the lower insulating layer 110 formed on the peripheral circuit structure PS is shown first.

FIGS. 6 to 23 are cross-sectional views showing a method of manufacturing a semiconductor device according to an embodiment.

Referring to FIG. 6, the bit lines BL may be formed on the lower insulating layer 110.

The lower insulating layer 110 may include insulating layers stacked in multiple layers. For example, the lower insulating layer 110 may include a silicon oxide layer, a silicon nitride layer, a silicon oxynitride layer, and/or a low-k dielectric layer.

The bit lines BL extend in the first direction (Y direction) and may be disposed to be spaced apart in the second direction (X direction) that intersects the first direction (Y direction). For example, the second direction (X direction) may be perpendicular to the first direction (Y direction). The bit lines BL may be formed by depositing a conductive layer on the lower insulating layer 110 and then patterning the conductive layer.

Although not shown, the space between the bit lines BL may be filled with an insulating material. The insulating material may include the same insulating material as the lower insulating layer 110, but is not limited thereto. If the insulating material includes the same insulating material as the lower insulating layer 110, the insulating material may be integrated with the lower insulating layer 110. For example, the upper surface of the lower insulating layer 110 and the upper surface of the bit line BL may be located at substantially the same level.

Referring to FIG. 7, a first channel pattern material layer CP1_L may be formed on the bit lines BL and the lower insulating layer 110. According to an embodiment, the first channel pattern material layer CP1_L may be deposited through a PVD process.

According to an embodiment, the first channel pattern material layer CP1_L may include an oxide semiconductor material. The oxide semiconductor material may include at least two materials from In, Ga, Zn, Al, Sn, and Hf, and the composition may further include materials such as Si, Mg, Ta, La, Nd, Ce, Sc, Cr, Co, Nb, Mo, Ba, Gd, Ti, W, Pd, Ru, Ni, Mn, and the like. For example, the oxide semiconductor material may include IGZO. In an embodiment, the first channel pattern material layer CP1_L may include IGZO, but is not limited thereto.

The first channel pattern material layer CP1_L may include an oxide semiconductor material with better contact properties than an oxide semiconductor material in the second channel pattern material layer CP2_L described below. In some embodiments, the first channel pattern material layer CP1_L may include an oxide semiconductor material with a high indium composition ratio.

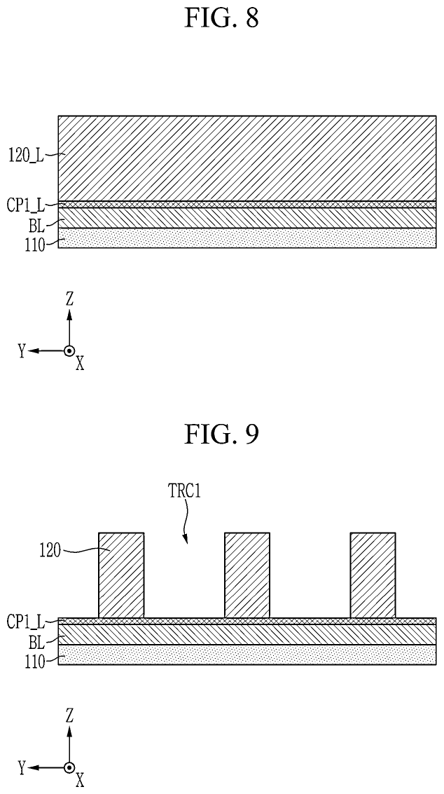

Referring to FIG. 8, a first insulating pattern material layer 120_L may be formed on the first channel pattern material layer CP1_L. For example, the first insulating pattern material layer 120_L may be deposited through a chemical vapor deposition or PVD process, but is not limited thereto.

The first insulating pattern material layer 120_L may include, for example, at least one of silicon oxide, silicon oxynitride, silicon nitride, or a low dielectric constant material with a smaller dielectric constant than silicon oxide, but is not limited thereto.

Referring to FIG. 9, the first insulating pattern 120 may be formed by patterning the first insulating pattern material layer 120_L.

The first insulating patterns 120 extend in the second direction (X direction) and may define first trenches TRC1 spaced apart from each other in the first direction (Y direction). The first trenches TRC1 may intersect the bit line BL, and the first trenches TRC1 may expose the upper surface of the first channel pattern material layer CP1_L.

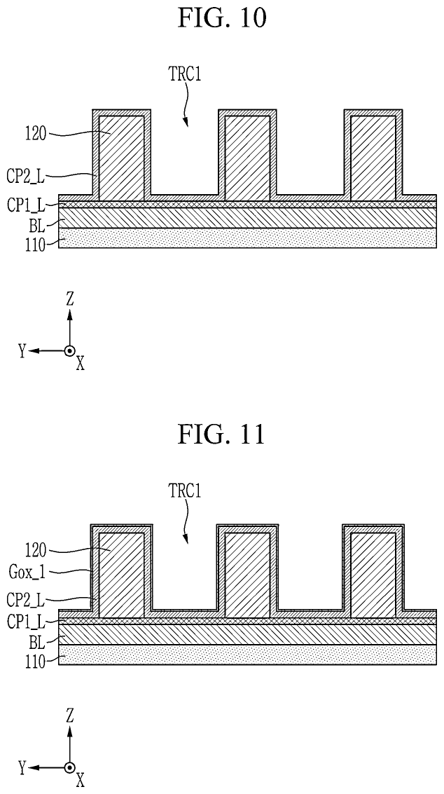

Referring to FIG. 10, a second channel pattern material layer CP2_L may be formed on the upper surfaces of the first insulating patterns 120 and in the first trench TRC1. According to an embodiment, the second channel pattern material layer CP2_L may be formed through an ALD process. In other words, the second channel pattern material layer CP2_L may be conformally deposited on the upper surface and the sidewall of the first insulating pattern 120 and the upper surface of the first channel pattern material layer CP1_L.

According to an embodiment, the second channel pattern material layer CP2_L may include an oxide semiconductor material. For example, the second channel pattern material layer CP2_L may include IGZO, but is not limited thereto.

In some embodiments, the second channel pattern material layer CP2_L may include an oxide semiconductor material that is different from the first channel pattern material layer CP1_L, or may include an oxide semiconductor material of a different composition ratio than the first channel pattern material layer CP1_L.

The second channel pattern material layer CP2_L may include an oxide semiconductor material to improve film reliability. In some embodiments, the second channel pattern material layer CP2_L may include an oxide semiconductor material with a high gallium composition ratio. The second channel pattern material layer CP2_L may include an oxide semiconductor material with a higher gallium composition ratio than that of the oxide semiconductor material of the first channel pattern material layer CP1_L. The first channel pattern material layer CP1_L may include an oxide semiconductor material with a higher indium composition ratio than that of the oxide semiconductor material of the second channel pattern material layer CP2_L.

Referring to FIG. 11, a first gate insulating pattern material layer Gox_1 may be formed to conformally cover the second channel pattern material layer CP2_L. For example, the first gate insulating pattern material layer Gox_1 may be deposited through a CVD, PVD, or ALD process, but is not limited thereto.

The first gate insulating pattern Gox_1 may include silicon oxide, silicon oxynitride, a high dielectric constant material having a higher dielectric constant than silicon oxide, or a combination thereof. The high dielectric constant material may include metal oxide or metal nitride.

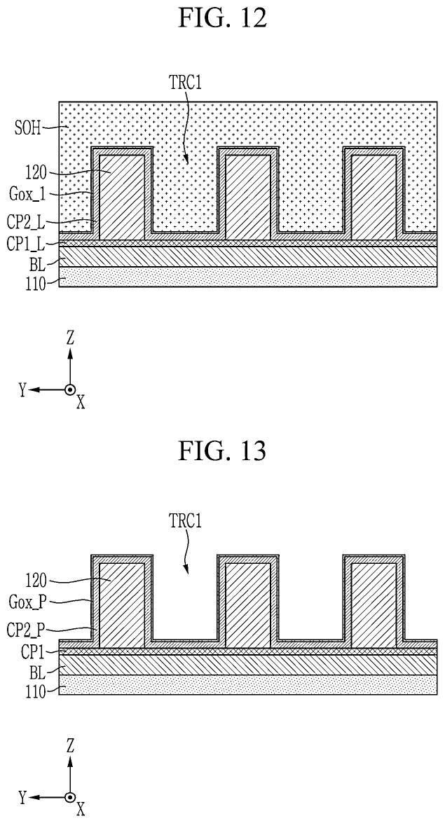

Referring to FIG. 12, a spin-on hardmask layer (SOH) may be formed on the first gate insulating pattern material layer Gox_1. The spin-on hardmask layer (SOH) may be formed through a spin coating process. For example, the spin-on hardmask layer (SOH) may include carbon, but is not limited thereto.

Next, the spin-on hard mask layer (SOH) may be patterned to form a spin-on hard mask pattern, and the spin-on hard mask pattern may be used as an etch mask to etch the first channel pattern material layer CP1_L and the second channel pattern material layer CP2_L.

Referring to FIG. 13, the patterning of the first channel pattern material layer CP1_L may be completed through an etching process to form the first channel pattern CP1, and the second channel pattern material layer CP2_L may be initially patterned to form a preliminary second channel pattern CP2_P. Next, the spin-on hardmask pattern may be removed. For example, the spin-on hardmask pattern may be removed through an ashing or strip process.

According to an embodiment, the first channel pattern CP1 may include a portion extending along the first direction (Y direction) on the bit line BL. Portions of the first channel pattern CP1 extending along the first direction (Y direction) may be spaced apart along the second direction (X direction). The first channel pattern CP1 may include a portion extending along the second direction (X direction). Portions of the first channel pattern CP1 extending along the second direction (X direction) may be spaced apart along the first direction (Y direction). That is, the first channel pattern CP1 may have a mesh shape.

The first insulating patterns 120 may be located on portions of the first channel pattern CP1 extending along the second direction (X direction).

The preliminary second channel pattern CP2_P may extend along the first direction (Y direction) on the first channel pattern CP1 and the first insulating patterns 120. The preliminary second channel pattern CP2_P may cover the upper surface of the first channel pattern CP1 and the sidewall and upper surface of the first insulating pattern 120 along the first direction (Y direction). The preliminary second channel patterns CP2_P may be spaced apart along the second direction (X direction).

Additionally, the first gate insulating pattern material layer Gox_1 may be patterned through an etching process to form a preliminary gate insulating pattern Gox_P. The preliminary gate insulating pattern Gox_P may be located on the preliminary second channel pattern CP2_P. The preliminary gate insulating pattern Gox_P may extend along the first direction (Y direction) on the preliminary second channel pattern CP2_P. The preliminary gate insulating patterns Gox_P may be spaced apart along the second direction (X direction).

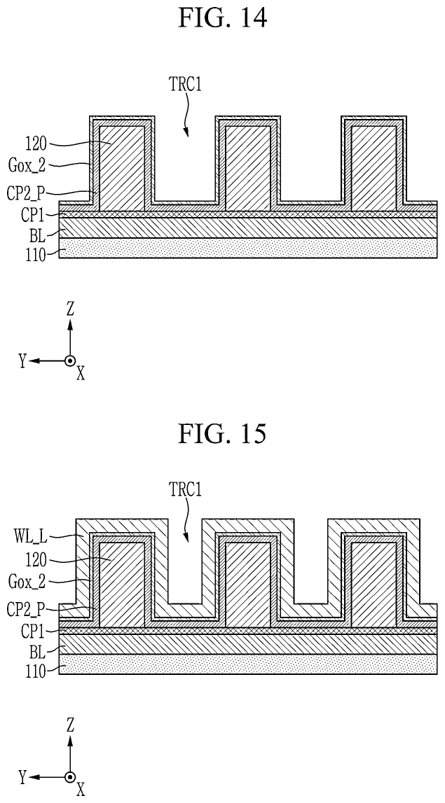

Referring to FIG. 14, a second gate insulating pattern material layer Gox_2 may be formed to conformally cover the preliminary gate insulating pattern Gox_P. For example, the second gate insulating pattern material layer Gox_2 may be deposited through a CVD, PVD, or ALD process, but is not limited thereto.

The second gate insulating pattern material layer Gox_2 may include the same material as the first gate insulating pattern material layer Gox_1. The second gate insulating pattern material layer Gox_2 may be integrated with the preliminary gate insulating pattern Gox_P of FIG. 13.

Referring to FIG. 15, a word line material layer WL_L may be formed to conformally cover the second gate insulating pattern material layer Gox_2. For example, the word line material layer WL_L may be deposited through a CVD, PVD, or ALD process, but is not limited thereto.

The word line material layer WL_L may include doped polysilicon, metal, conductive metal nitride, conductive metal silicide, conductive metal oxide, or a combination thereof.

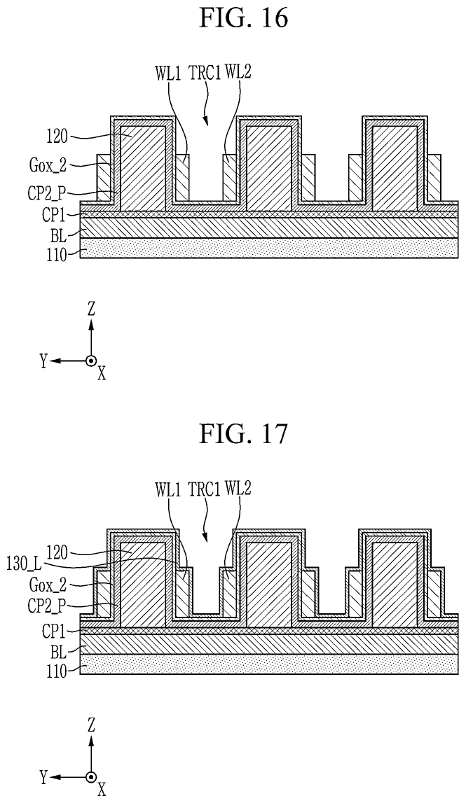

Referring to FIG. 16, an anisotropic etching process may be performed on the word line material layer WL_L to form a pair of word lines WL1 and WL2 spaced apart from each other in the first direction (Y direction) in the first trench TRC1.

During an anisotropic etching process for the word line material layer WL_L, the upper surfaces of the word lines WL1 and WL2 may be lower than the upper surface of the second channel pattern CP2 and the upper surface of the first insulating pattern 120. In some embodiments, an etching process may be additionally performed to recess the upper surfaces of the word lines WL1 and WL2.

Referring to FIG. 17, a second insulating pattern material layer 130_L may be formed to conformally cover the second gate insulating pattern material layer Gox_2 and the word lines WL1 and WL2. For example, the second insulating pattern material layer 130_L may be deposited through a CVD, PVD, or ALD process, but is not limited thereto.

The second insulating pattern material layer 130_L may include, for example, at least one of silicon oxide, silicon oxynitride, silicon nitride, or a low dielectric constant material that has a lower dielectric constant than silicon oxide, but is not limited thereto.

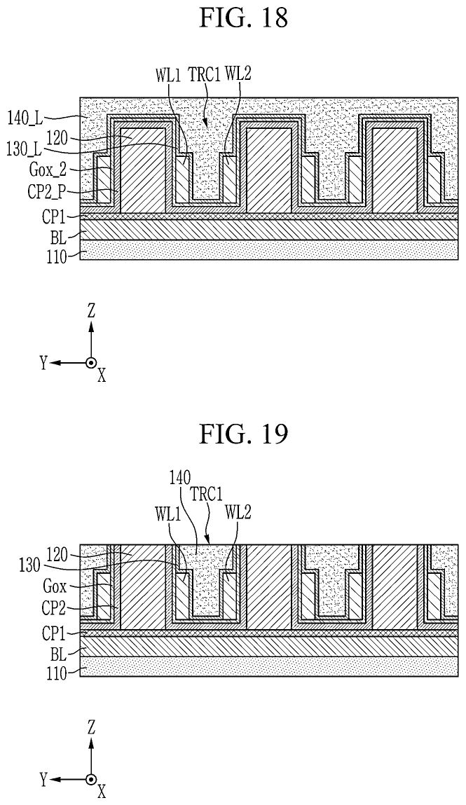

Referring to FIG. 18, a third insulating pattern material layer 140_L may be formed to fill the first trench TRC1 remaining after the second insulating pattern material layer 130_L is formed. The third insulating pattern material layer 140_L may cover the upper surface of the first trench TRC1 and the upper surface of the second insulating pattern material layer 130_L. For example, the third insulating pattern material layer 140_L may be deposited through a CVD, PVD, or ALD process, but is not limited thereto.

The third insulating pattern material layer 140_L may include, for example, at least one of silicon oxide, silicon oxynitride, silicon nitride, or a low dielectric constant material that has a lower dielectric constant than silicon oxide, but is not limited thereto.

The third insulating pattern material layer 140_L may include a material different from that of the second insulating pattern material layer 130_L, but is not limited thereto. When the second insulating pattern material layer 130_L and the third insulating pattern material layer 140_L include the same material, they may be integrally formed.

Referring to FIG. 19, the second channel pattern CP2, the gate insulating pattern Gox, the second insulating pattern 130, and the third insulating pattern 140 may be formed through a planarization process. Through the planarization process, the upper surface of the first insulating pattern 120, the upper surface of the second channel pattern CP2, the upper surface of the gate insulating pattern Gox, the upper surface of the second insulating pattern 130, and the upper surface of the insulating pattern 140 may be exposed. That is, the portion of the preliminary second channel pattern CP2_P, the portion of the second gate insulating pattern material layer Gox_2, the portion of the second insulating pattern material layer 130_L, and the portion of the third insulating pattern material layer 140_L located at a higher level than the upper surface of the first insulating pattern 120 may be removed through a planarization process.

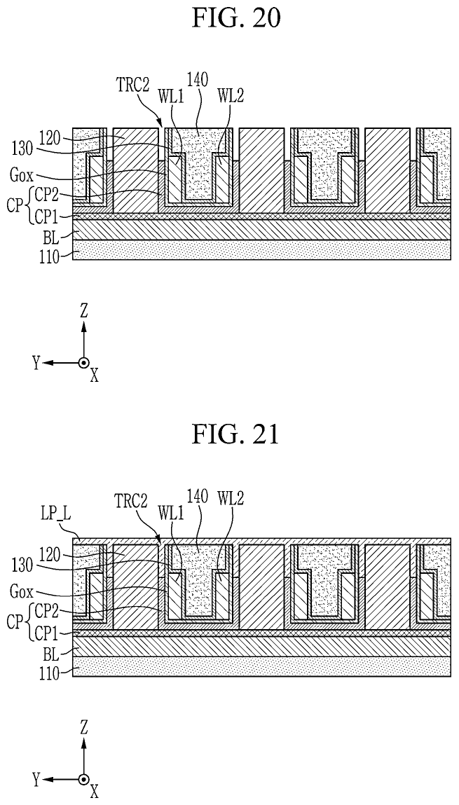

Referring to FIG. 20, the second trench TRC2 may be formed through an etching process to recess a portion of the second channel pattern CP2.

Specifically, by etching the second channel pattern CP2 from the upper surface toward the lower surface, the second trench TRC2 extending in the third direction (Z direction) may be formed. For example, a portion of the second channel pattern CP2 may be wet-etched using an etchant that selectively etches the second channel pattern CP2. However, the etching process for recessing the second channel pattern CP2 is not limited thereto, and may be changed in various ways.

Referring to FIG. 21, a landing pad material layer LP_L may be formed to cover the upper surfaces of the insulating patterns 120, 130, and 140 and the upper surface of the gate insulating pattern Gox, and to fill the second trench TRC2. The landing pad material layer LP_L fills the second trench TRC2 and may contact the upper surface of the second channel pattern CP2.

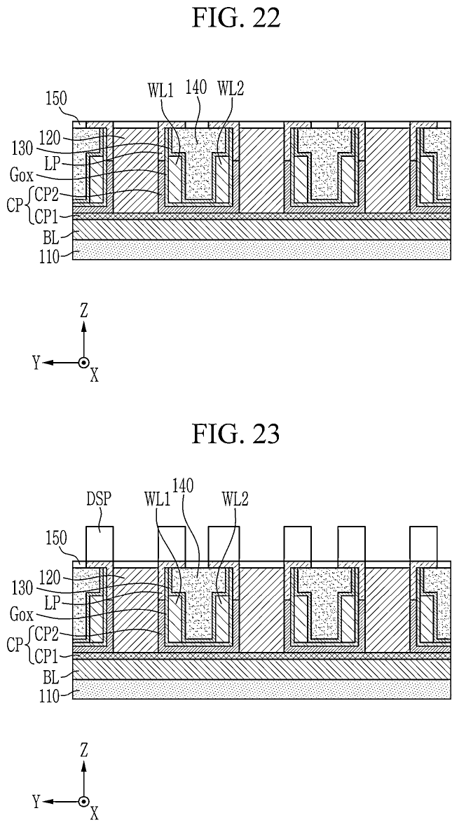

Referring to FIG. 22, after the landing pad material layer LP_L is patterned to form holes exposing the upper surfaces of the first and third insulating patterns 120 and 140, the interlayer insulating layer 150 may be embedded in the holes, and then a planarization process may be performed. Accordingly, landing pads LP may be formed. However, the order of forming the landing pads LP and the interlayer insulating layer 150 is not limited thereto.

In some embodiments, after forming and patterning the interlayer insulating layer 150 on the insulating patterns 120, 130, and 140, the gate insulating pattern Gox, and the second channel pattern CP2, the landing pads LP penetrating the interlayer insulating layer 150 may be formed.

Referring to FIG. 23, data storage patterns DSP may be formed on the landing pads LP, respectively. In an embodiment, the data storage pattern DSP may be a capacitor including a lower electrode, a capacitor dielectric layer, and an upper electrode. In this case, the lower electrode may be in contact with the landing pad LP.

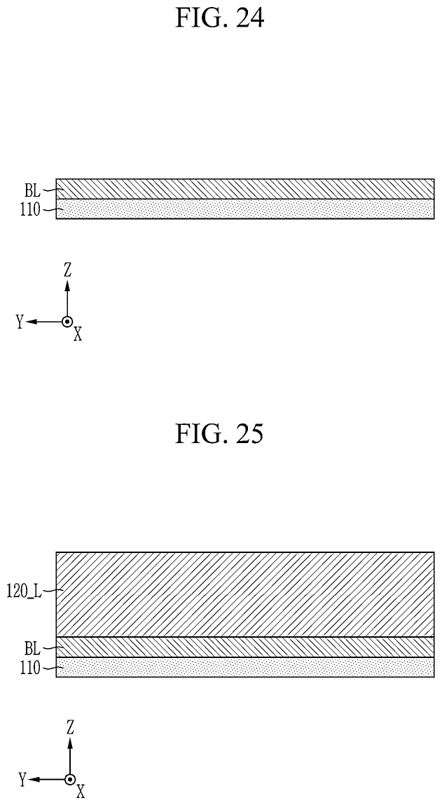

Hereinafter, with reference to FIGS. 24 to 41, a method of manufacturing a semiconductor device according to the embodiment shown in FIGS. 4 and 5 will be described. In FIGS. 24 to 41, for convenience, the peripheral circuit structure PS of FIGS. 4 and 5 is omitted, and the lower insulating layer 110 formed on the peripheral circuit structure PS is shown first.

FIGS. 24 to 41 are cross-sectional views showing a method of manufacturing a semiconductor device according to an embodiment.

Referring to FIG. 24, bit lines BL may be formed on the lower insulating layer 110.

The lower insulating layer 110 may include insulating layers stacked in multiple layers. For example, the lower insulating layer 110 may include a silicon oxide layer, a silicon nitride layer, a silicon oxynitride layer, and/or a low-k dielectric layer.

The bit lines BL extend in the first direction (Y direction) and may be disposed to be spaced apart in the second direction (X direction) that intersects the first direction (Y direction). For example, the second direction (X direction) may be perpendicular to the first direction (Y direction). The bit lines BL may be formed by depositing a conductive layer on the lower insulating layer 110 and then patterning the conductive layer.

Although not shown, the space between the bit lines BL may be filled with an insulating material. The insulating material may include the same insulating material as the lower insulating layer 110, but is not limited thereto. If the insulating material includes the same insulating material as the lower insulating layer 110, the insulating material may be integrated with the lower insulating layer 110. For example, the upper surface of the lower insulating layer 110 and the upper surface of the bit line BL may be located at substantially the same level.

Referring to FIG. 25, a first insulating pattern material layer 120_L may be formed on the bit lines BL and the lower insulating layer 110. For example, the first insulating pattern material layer 120_L may be deposited through a CVD or PVD process, but is not limited thereto.

The first insulating pattern material layer 120_L may include, for example, at least one of silicon oxide, silicon oxynitride, silicon nitride, or a low dielectric constant material with a smaller dielectric constant than silicon oxide, but is not limited thereto.

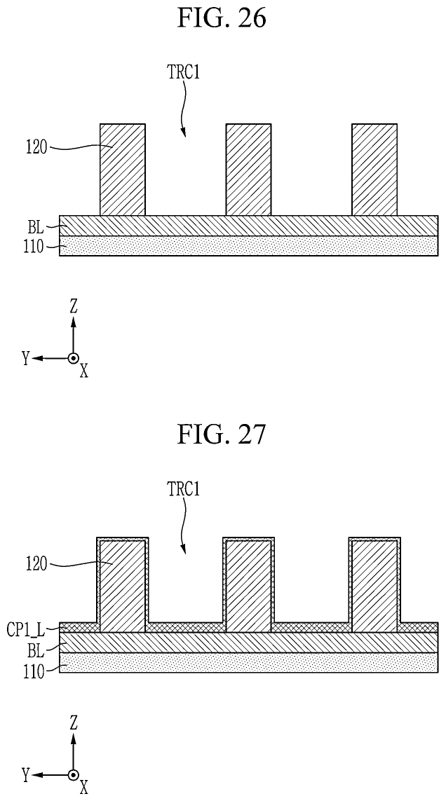

Referring to FIG. 26, the first insulating pattern 120 may be formed by patterning the first insulating pattern material layer 120_L.

The first insulating patterns 120 extend in the second direction (X direction) and may define first trenches TRC1 spaced apart from each other in the first direction (Y direction). The first trenches TRC1 may intersect the bit line BL, and the first trenches TRC1 may expose the upper surface of the bit line BL.

Referring to FIG. 27, the first channel pattern material layer CP1_L may be formed on the upper surfaces of the first insulating patterns 120 and in the first trench TRC1. According to an embodiment, the first channel pattern material layer CP1_L may be formed through a PVD process. Accordingly, the thickness of the second channel pattern material layer CP2_L deposited on the upper surface of the first insulating pattern 120 and the upper surface of the bit line BL may be thicker than the thickness of the second channel pattern material layer CP2_L deposited on the sidewall of the first insulating pattern 120.

According to an embodiment, the first channel pattern material layer CP1_L may include an oxide semiconductor material. The oxide semiconductor material may include at least two materials from In, Ga, Zn, Al, Sn, and Hf, and the composition may further include materials such as Si, Mg, Ta, La, Nd, Ce, Sc, Cr, Co, Nb, Mo, Ba, Gd, Ti, W, Pd, Ru, Ni, Mn, and the like. For example, the oxide semiconductor material may include IGZO. In an embodiment, the first channel pattern material layer CP1_L may include IGZO, but is not limited thereto.

The first channel pattern material layer CP1_L may include an oxide semiconductor material with better contact properties than an oxide semiconductor material in the second channel pattern material layer CP2_L described below. In some embodiments, the first channel pattern material layer CP1_L may include an oxide semiconductor material with a high indium composition ratio.

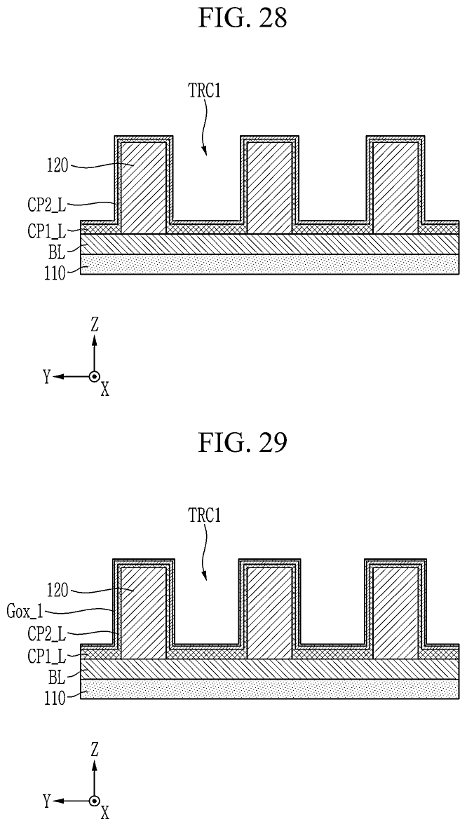

Referring to FIG. 28, the second channel pattern material layer CP2_L may be formed to conformally cover the first channel pattern material layer CP1_L. According to an embodiment, the second channel pattern material layer CP2_L may be formed through an ALD process. Accordingly, the thickness of the second channel pattern material layer CP2_L deposited on the first channel pattern material layer CP1_L deposited on the upper surface of the first insulating pattern 120 and the upper surface of the bit line BL may be substantially the same as the thickness of the second channel pattern material layer CP2_L deposited on the first channel pattern material layer CP1_L deposited on the first insulating pattern 120.

According to an embodiment, the second channel pattern material layer CP2_L may include an oxide semiconductor material. For example, the second channel pattern material layer CP2_L may include IGZO, but is not limited thereto.

In some embodiments, the second channel pattern material layer CP2_L may include an oxide semiconductor material different from the first channel pattern material layer CP1_L, or an oxide semiconductor material with a different composition ratio than that of the first channel pattern material layer CP1_L.

The second channel pattern material layer CP2_L may include an oxide semiconductor material to improve film reliability. In some embodiments, the second channel pattern material layer CP2_L may include an oxide semiconductor material with a high gallium composition ratio. The second channel pattern material layer CP2_L may include an oxide semiconductor material with a higher gallium composition ratio than that of the oxide semiconductor material of the first channel pattern material layer CP1_L. The first channel pattern material layer CP1_L may include an oxide semiconductor material with a higher indium composition ratio than that of the oxide semiconductor material of the second channel pattern material layer CP2_L.

Referring to FIG. 29, the first gate insulating pattern material layer Gox_1 may be formed to conformally cover the second channel pattern material layer CP2_L. For example, the first gate insulating pattern material layer Gox_1 may be deposited through a CVD, PVD, or ALD process, but is not limited thereto.

The first gate insulating pattern material layer Gox_1 may include silicon oxide, silicon oxynitride, a high dielectric constant material having a higher dielectric constant than silicon oxide, or a combination thereof. The high dielectric constant material may include metal oxide or metal nitride.

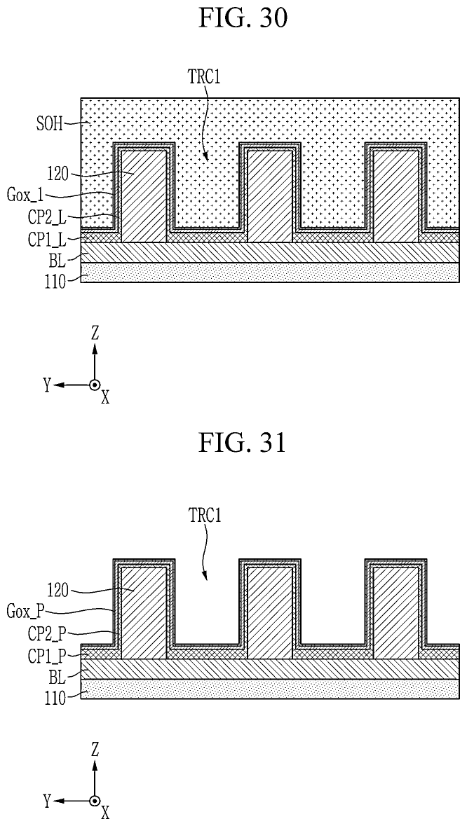

Referring to FIG. 30, a spin-on hard mask layer (SOH) may be formed on the first gate insulating pattern material layer Gox_1. The spin-on hardmask layer (SOH) may be formed through a spin coating process. For example, the spin-on hardmask layer (SOH) may include carbon, but is not limited thereto.

Next, the spin-on hard mask layer (SOH) may be patterned to form a spin-on hard mask pattern, and the spin-on hard mask pattern may be used as an etch mask to etch the first channel pattern material layer CP1_L and the second channel pattern material layer CP2_L.

Referring to FIG. 31, a first channel pattern material layer CP1_L may be patterned by the etching process to form a preliminary first channel pattern CP1_P, and a second channel pattern material layer CP2_L may be patterned to form a preliminary second channel pattern CP2_P.

Next, the spin-on hardmask pattern may be removed. For example, the spin-on hardmask pattern may be removed through ashing or strip process.

The preliminary first channel pattern CP1_P may extend along the first direction (Y direction) on the bit line BL and the first insulating patterns 120. The preliminary first channel pattern CP1_P may cover the upper surface of the bit line BL, and the sidewall and upper surface of the first insulating pattern 120 along the first direction (Y direction). The preliminary first channel patterns CP1_P may be spaced apart along the second direction (X direction).

The preliminary second channel pattern CP2_P may be located on the preliminary first channel pattern CP1_P. The preliminary second channel pattern CP2_P may extend along the first direction (Y direction) on the preliminary first channel pattern CP1_P. The preliminary second channel patterns CP2_P may be spaced apart along the second direction (X direction).

Additionally, the first gate insulating pattern material layer Gox_1 may be patterned through an etching process to form the preliminary gate insulating pattern Gox_P. The preliminary gate insulating pattern Gox_P may be located on the preliminary second channel pattern CP2_P. The preliminary gate insulating pattern Gox_P may extend along the first direction (Y direction) on the preliminary second channel pattern CP2_P. The preliminary gate insulating patterns Gox_P may be spaced apart along the second direction (X direction).

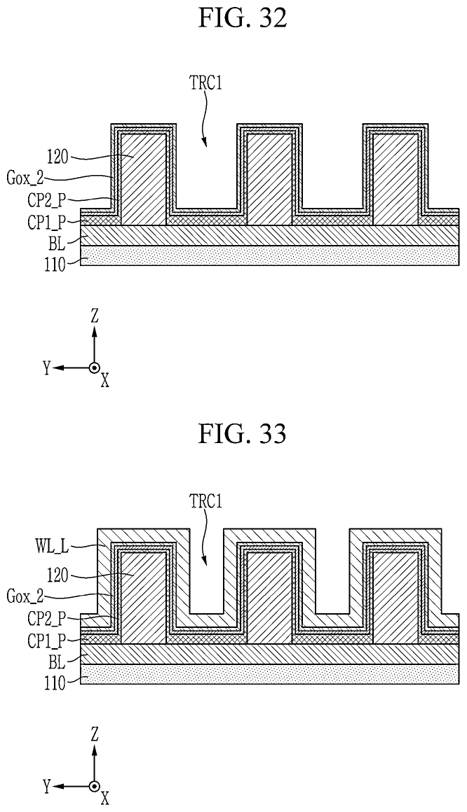

Referring to FIG. 32, the second gate insulating pattern material layer Gox_2 may be formed to conformally cover the preliminary gate insulating pattern Gox_P. For example, the second gate insulating pattern material layer Gox_2 may be deposited through a CVD, PVD, or ALD process, but is not limited thereto.

The second gate insulating pattern material layer Gox_2 may include the same material as the first gate insulating pattern material layer Gox_1. The second gate insulating pattern material layer Gox_2 may be integrated with the preliminary gate insulating pattern Gox_P of FIG. 31.

Referring to FIG. 33, the word line material layer WL_L may be formed to conformally cover the second gate insulating pattern material layer Gox_2. For example, the word line material layer WL_L may be deposited through a CVD, PVD, or ALD process, but is not limited thereto.

The word line material layer WL_L may include doped polysilicon, metal, conductive metal nitride, conductive metal silicide, conductive metal oxide, or a combination thereof.

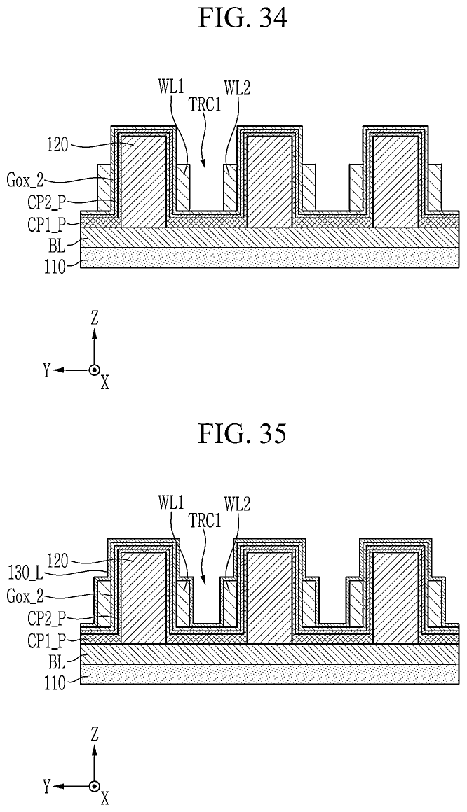

Referring to FIG. 34, an anisotropic etching process may be performed on the word line material layer WL_L to form a pair of word lines WL1 and WL2 spaced apart from each other in the first direction (Y direction) in the first trench TRC1.

During an anisotropic etching process for the word line material layer WL_L, the upper surfaces of the word lines WL1 and WL2 may be lower than the upper surface of the second channel pattern CP2 and the upper surface of the first insulating pattern 120. In some embodiments, an etching process may be additionally performed to recess the upper surfaces of the word lines WL1 and WL2.

Referring to FIG. 35, the second insulating pattern material layer 130_L may be formed to conformally cover the second gate insulating pattern material layer Gox_2 and the word lines WL1 and WL2. For example, the second insulating pattern material layer 130_L may be deposited through a CVD, PVD, or ALD process, but is not limited thereto.

The second insulating pattern material layer 130_L may include, for example, at least one of silicon oxide, silicon oxynitride, silicon nitride, or a low dielectric constant material that has a lower dielectric constant than silicon oxide, but is not limited thereto.

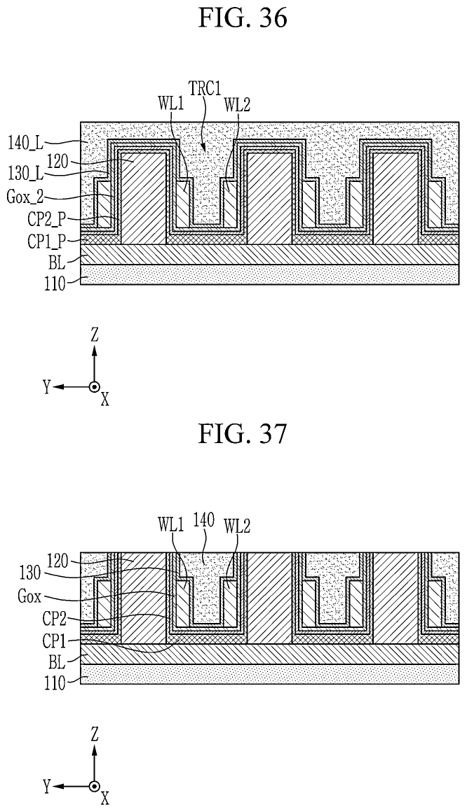

Referring to FIG. 36, the third insulating pattern material layer 140_L may be formed to fill the first trench TRC1 remaining after the second insulating pattern material layer 130_L is formed. The third insulating pattern material layer 140_L may cover the upper surface of the first trench TRC1 and the upper surface of the second insulating pattern material layer 130_L. For example, the third insulating pattern material layer 140_L may be deposited through a CVD, PVD, or ALD process, but is not limited thereto.

The third insulating pattern material layer 140_L may include, for example, at least one of silicon oxide, silicon oxynitride, silicon nitride, or a low dielectric constant material that has a lower dielectric constant than silicon oxide, but is not limited thereto.

The third insulating pattern material layer 140_L may include a material different from that of the second insulating pattern material layer 130_L, but is not limited thereto. When the second insulating pattern material layer 130_L and the third insulating pattern material layer 140_L include the same material, they may be integrally formed.

Referring to FIG. 37, the first channel pattern CP1, the second channel pattern CP2, the gate insulating pattern Gox, the second insulating pattern 130, and the third insulating pattern 140 may be formed through a planarization process. Through the planarization process, the upper surface of the first insulating pattern 120, the upper surface of the first channel pattern CP1, the upper surface of the second channel pattern CP2, the upper surface of the gate insulating pattern Gox, the upper surface of the second insulating pattern 130, and the upper surface of the third insulating pattern 140 may be exposed. That is, the portion of the preliminary first channel pattern CP1_P, the portion of the preliminary first channel pattern CP2_P, the portion of the second gate insulating pattern material layer Gox_2, the portion of the second insulating pattern material layer 130_L, and the portion of the third insulating pattern material layer 140_L located at a higher level than the upper surface of the first insulating pattern 120 may be removed by a planarization process.

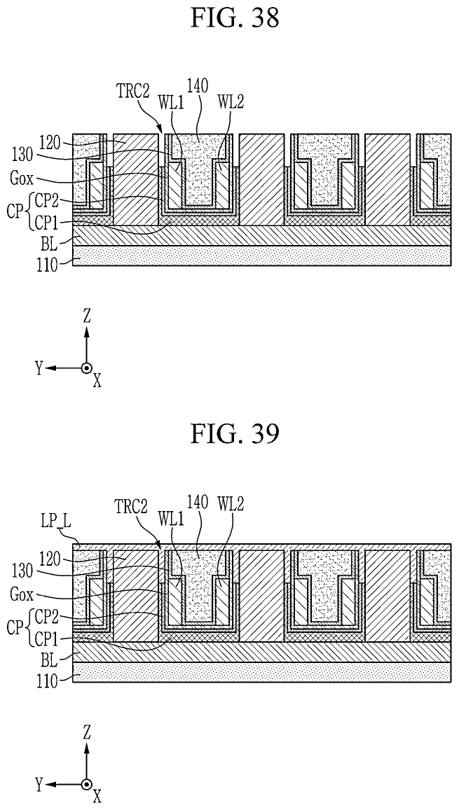

Referring to FIG. 38, the second trench TRC2 may be formed through an etching process to recess portions of the first channel pattern CP1 and the second channel pattern CP2.

Specifically, by etching the first channel pattern CP1 and the second channel pattern CP2 from the upper surface toward the lower surface, the second trench TRC2 extending in the third direction (Z direction) may be formed. For example, a portion of the first channel pattern CP1 and a portion of the second channel pattern CP2 may be wet-etched using an etchant that selectively etches the first channel pattern CP1 and the second channel pattern CP2. However, the etching process for recessing the first channel pattern CP1 and the second channel pattern CP2 is not limited thereto, and may be changed in various ways.

In an embodiment, the upper surface of the first channel pattern CP1 and the upper surface of the second channel pattern CP2 in the second trench TRC2 may be located at substantially the same level, but the present disclosure is not limited thereto. For example, in the second trench TRC2, the upper surface of the first channel pattern CP1 and the upper surface of the second channel pattern CP2 may be located at different levels.

Referring to FIG. 39, the landing pad material layer LP_L may be formed to cover the upper surfaces of the insulating patterns 120, 130, and 140 and the upper surface of the gate insulating pattern Gox, and to fill the second trench TRC2. The landing pad material layer LP_L may fill the second trench TRC2 and may contact the upper surfaces of the first channel pattern CP1 and the second channel pattern CP2.

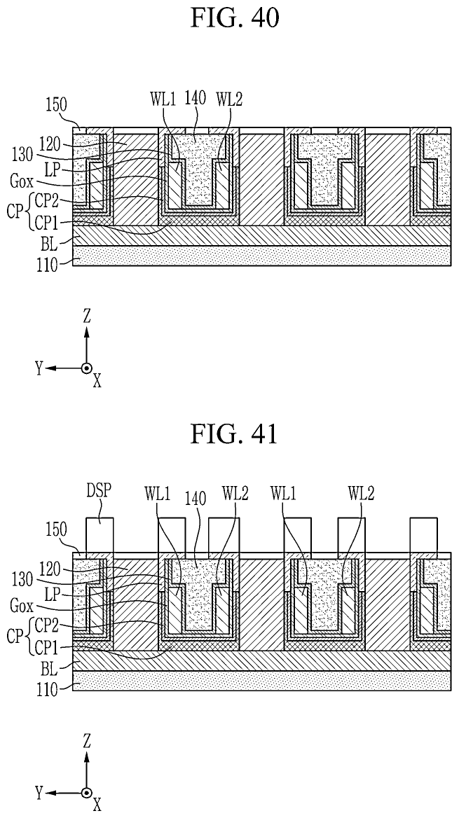

Referring to FIG. 40, after the landing pad material layer LP_L is patterned to form holes exposing the upper surfaces of the first and third insulating patterns 120 and 140, the interlayer insulating layer 150 may be embedded in the holes, and then a planarization process may be performed. Accordingly, the landing pads LP may be formed. However, the order of forming the landing pads LP and the interlayer insulating layer 150 is not limited thereto.

In some embodiments, after forming and patterning the interlayer insulating layer 150 on the insulating patterns 120, 130, and 140, the gate insulating pattern Gox, the first channel pattern CP1 and the second channel pattern CP2, the landing pads LP penetrating the interlayer insulating layer 150 may be formed.

Referring to FIG. 41, the data storage patterns DSP may be formed on the landing pads LP, respectively. In an embodiment, the data storage pattern DSP may be a capacitor including a lower electrode, a capacitor dielectric layer, and an upper electrode. In this case, the lower electrode may be in contact with the landing pad LP.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A semiconductor device, comprising:
a substrate;
a bit line on the substrate and extending in a first direction;
a first insulating pattern on the bit line and extending in a second direction, the second direction intersecting the first direction;
a channel pattern contacting a sidewall of the first insulating pattern and the bit line, the channel pattern including an oxide semiconductor material;
a word line extending in the second direction and spaced apart from the channel pattern;
a gate insulating pattern between the channel pattern and the word line;
a second insulating pattern on the word line and the gate insulating pattern; and
a landing pad electrically connected to the channel pattern, wherein
the channel pattern includes a first portion and a second portion,
the first portion of the channel pattern is between the gate insulating pattern and the first insulating pattern,
the second portion of the channel pattern is between the gate insulating pattern and the bit line,
a thickness of the second portion of the channel pattern is thicker than a thickness of the first portion of the channel pattern.

2. The semiconductor device of claim 1, wherein
the channel pattern comprises a first channel pattern and a second channel pattern,
the first channel pattern is above the bit line, and
the second channel pattern is on a sidewall of the first insulating pattern and a upper surface of the first channel pattern.

3. The semiconductor device of claim 2, wherein
the second channel pattern has a conformal shape.

4. The semiconductor device of claim 2, wherein
the first channel pattern is between the bit line and the first insulating pattern,
the second channel pattern is along a sidewall of the first insulating pattern.

5. The semiconductor device of claim 4, wherein
the landing pad is in contact with the second channel pattern.

6. The semiconductor device of claim 2, wherein
the first channel pattern is between the bit line and the second channel pattern and between the first insulating pattern and the second channel pattern, and
the second channel pattern is spaced apart from the first insulating pattern.

7. The semiconductor device of claim 6, wherein
a thickness of a portion of the first channel pattern between the bit line and the second channel pattern is thicker than a thickness of the portion of the first channel pattern between the first insulating pattern and the second channel pattern.

8. The semiconductor device of claim 6, wherein
the landing pad is in contact with the first channel pattern and the second channel pattern.

9. The semiconductor device of claim 2, wherein
the oxide semiconductor material of the channel pattern is in the first channel pattern and the second channel pattern, and
an indium composition ratio of the oxide semiconductor material in the first channel pattern is higher than an indium composition ratio of an oxide semiconductor material in the second channel pattern.

10. The semiconductor device of claim 2, wherein
the oxide semiconductor material of the channel pattern is in the first channel pattern and the second channel pattern,
a gallium composition ratio of an oxide semiconductor material in the second channel pattern is higher than a gallium composition ratio of an oxide semiconductor material in the first channel pattern.

11. A semiconductor device, comprising:
a substrate;
a bit line on the substrate and extending in a first direction;
a first insulating pattern on the bit line and extending in a second direction, the second direction intersecting the first direction;
a channel pattern on an upper surface of the bit line and a sidewall of the first insulating pattern, the channel pattern including an oxide semiconductor material;
a word line extending in the second direction and spaced apart from the channel pattern;
a gate insulating pattern between the channel pattern and the word line;
a second insulating pattern on the word line and the gate insulating pattern; and
a landing pad electrically connected to the channel pattern, wherein
the channel pattern includes a first channel pattern and a second channel pattern,
the first channel pattern is between the bit line and the first insulating pattern, and
the second channel pattern is on an upper surface of the first channel pattern and a sidewall of the first insulating pattern.

12. The semiconductor device of claim 11, wherein
the second channel pattern has a conformal shape.

13. The semiconductor device of claim 11, wherein
a first portion of the first channel pattern extends in the first direction along the bit line, and
a second portion of the first channel pattern extends in the second direction across the bit line.

14. The semiconductor device of claim 11, wherein
the landing pad is in contact with the second channel pattern.

15. The semiconductor device of claim 11, wherein
the oxide semiconductor material in the channel pattern is different in the first channel pattern and the second channel pattern.

16. A semiconductor device, comprising:
a substrate;
a bit line on the substrate and extending in a first direction;
a first insulating pattern on the bit line and extending in a second direction, the second direction intersecting the first direction;
a channel pattern on an upper surface of the bit line and a sidewall of the first insulating pattern, the channel pattern including an oxide semiconductor material;
a word line extending in the second direction and spaced apart from the channel pattern;
a gate insulating pattern between the channel pattern and the word line;
a second insulating pattern on the word line and the gate insulating pattern; and
a landing pad electrically connected to the channel pattern, wherein
the channel pattern includes a first channel pattern and a second channel pattern,
the first channel pattern extends from an upper surface of the bit line onto a sidewall of the first insulating pattern, and
the second channel pattern is between the first channel pattern and the gate insulating pattern.

17. The semiconductor device of claim 16, wherein
a portion of the channel pattern on a upper surface of the bit line is thicker than a portion of the channel pattern on the sidewall of the first insulating pattern.

18. The semiconductor device of claim 16, wherein
the landing pad is in contact with the first channel pattern and the second channel pattern.

19. The semiconductor device of claim 16, wherein
the oxide semiconductor material comprises indium gallium zinc oxide (IGZO), and
the oxide semiconductor material of the channel pattern is in the first channel pattern and the second channel pattern,
a composition ratio of indium, gallium, zinc, and oxygen in the first channel pattern and a composition ratio of indium, gallium, zinc, and oxygen in the second channel pattern are different from each other.

20. The semiconductor device of claim 19, wherein
an indium composition ratio of an oxide semiconductor material in the first channel pattern is higher than an indium composition ratio of an oxide semiconductor material in the second channel pattern, and
a gallium composition ratio of an oxide semiconductor material in the second channel pattern is higher than a gallium composition ratio of an oxide semiconductor material in the first channel pattern.
